(19) United States
(12) Patent Application Publication
(10) Pub. No.: US 2026/0189191 A1
(43) Pub. Date: Jul. 2, 2026

(54) ELECTRONIC CIRCUIT AND METHOD FOR SUPPRESSING OFFSET CHANGES IN A BUFFER

(71) Applicant: Robert Bosch GmbH, Stuttgart (DE)

(72) Inventors: Amin Jemili, Kusterdingen (DE); Steffen Becker, Coswig (DE)

(21) Appl. No.: 19/377,507

(22) Filed: Nov. 3, 2025

(30) Foreign Application Priority Data
Nov. 7, 2024 (DE) 10 2024 210 687.9

(51) Int. Cl. H03F 1/02; H03F 1/26; H03F 3/45

(52) U.S. Cl. CPC H03F 1/0288; H03F 1/26; H03F 3/4539; H03F 2200/331; H03F 2200/375

(57) ABSTRACT

An electronic circuit and a method for suppressing offset changes in a buffer. The electronic circuit includes: the buffer, which is configured to provide the electrical output signal based on an input signal at an input of the electronic circuit, wherein the buffer is arranged in a main path of the electronic circuit. The electronic circuit further includes an auxiliary path that is arranged parallel to the main path and comprises at least the following elements: an electronic amplifier, which is connected to the input to generate a control signal for the buffer based on the input signal, and an arrangement of chopper switches in order to minimize, in particular suppress, the offset changes in the auxiliary path by the arrangement of the chopper switches.

### FIELD

The present invention relates to an electronic circuit and a method for suppressing offset changes in a buffer.

### BACKGROUND INFORMATION

A key component of an electronic signal-processing chain is the reference buffer. These buffers have the particular task of converting a reference voltage, which is normally high-impedance (i.e., with high resistance), into a low-impedance (i.e., with low resistance) voltage. One reason for this is that a low-impedance voltage is better able to drive other electronic components such as resistors, capacitors or inductors without a significant voltage drop (also called “IR drop”) occurring. An “IR drop” refers to the voltage loss caused by the current flow in a resistor.

Any electronic component can exhibit what is known as random telegraph noise. Random telegraph noise (RTN) is a form of noise signal that occurs in electronic components, especially in semiconductors such as transistors. It is a random fluctuation noise characterized by the sudden switching between two or more discrete states of the electrical signal. These states can be caused by the trapping and releasing of charge carriers in defect sites or in so-called “traps” in the material. For example, the reference buffer in its input pair can suddenly have an additional offset source, which, e.g., disappears again in a few seconds, or assumes a different discrete value.

Chopper modulation can be used against the random telegraph noise signal; however, chopper modulation is not a suitable solution for use in some systems, since the signal is not removed but merely modulated, in particular when this signal is used as a reference in a so-called sigma-delta analog-to-digital converter. This can massively degrade performance by demodulating quantization noise. Furthermore, it is often necessary that the signal can be made available continuously. Moreover, noise is also frequently a parameter that needs to be optimized.

### SUMMARY

The present invention relates to an electronic circuit and to a method. Features and details of the present invention can be found in the disclosure herein. Features and details that are described in connection with the electronic circuit according to the present invention of course also apply in connection with the method according to the present invention, and vice versa in each case, so that mutual reference can also always be made with regard to the disclosure of the present invention.

The present invention relates in particular to an electronic circuit for suppressing offset changes in a buffer for providing an electrical output signal, in particular a reference buffer. According to an example embodiment of the present invention, the electronic circuit includes:
The buffer, which is configured to provide the electrical output signal on the basis of an input signal at an input of the electronic circuit, wherein the buffer is arranged in a main path of the electronic circuit, wherein the buffer can also be referred to and understood as a reference buffer or reference amplifier, or can be configured as such, for example a reference buffer or reference amplifier for a sigma-delta analog-to-digital converter,
   wherein the electronic circuit further comprises an auxiliary path that is arranged parallel to the main path and comprises at least the following elements:
An electronic amplifier, in particular an operational amplifier, particularly preferably a transconductance amplifier, which is connected to the input in order to generate a control signal for the buffer on the basis of the input signal, so that the buffer can advantageously provide the output signal with suppressed offset changes using the control signal, and
An arrangement of chopper switches, in order to minimize, and in particular suppress, the offset changes in the auxiliary path by the arrangement of the chopper switches, wherein the arrangement of the chopper switches preferably comprises at least two and more preferably three chopper switches.

An offset change in an electronic circuit refers in particular to a change in a static direct current or a direct voltage that is applied to an amplifier, i.e., for example, the buffer according to the present invention, or another electronic circuit, in order to influence the output signal. This change can be caused by modifications to circuit elements or by external factors such as temperature or aging of components. An offset change can affect the accuracy and stability of the output signal. In this context, a reference buffer is used in particular to convert a high-impedance reference voltage into a low-impedance source, wherein the high-impedance reference voltage corresponds in particular to the input signal and the low-impedance source corresponds in particular to the output signal. This low impedance is necessary, for example, to keep the reference voltage stable and capable of carrying load, so that it can drive a resistor, a capacitor or an inductor, or according to the present invention a capacitive sensor, precisely and without voltage losses (often called “IR drop”). Typical characteristics of a reference buffer can include, for example, a high input impedance and a low output impedance. Due to the high input impedance, it can be prevented that the reference voltage is influenced or loaded by the buffer itself. Due to the low output impedance, it is ensured that the voltage remains stable even under changing loads and that currents can flow without significant voltage drops thereby arising. Due to this transformation from high impedance to low impedance, the reference voltage can be shielded against external influences and remain stable.

A transconductance amplifier (also referred to as an operational transconductance amplifier, OTA) is, in particular, an electronic amplifier that converts an input voltage into a proportional output current. Its function consists, for example, in making the output current (Iout) proportional to the applied input voltage (Vin), with a gain that is referred to as transconductance (gm).

A chopper switch is, in particular, an electronic switching element that can be used to periodically switch direct voltage or direct current on and off in rapid succession. Due to the decomposition of a signal into these rapid switching operations (chopping), more precise control and processing can be achieved. Chopper switches can be used, e.g., to reduce noise and drift at low frequencies. They offer a particularly efficient switching method, since they can minimize power losses by operating either fully conductive or non-conductive.

According to the method of the present invention, the electronic amplifier is able to precisely measure the input signal and generate a control signal that compensates for the error between the main path and the auxiliary path. The chopper switches, in particular, make a modulated transmission of the input signal possible in the auxiliary path, which effectively reduces random telegraph noise (RTN) and offsets.

A further advantage may be that the electronic amplifier is an integrating amplifier. As a result, it is ensured, in particular, that the electronic amplifier exhibits an infinitely large gain when using direct current (DC).

In a further possibility, the output signal of the buffer can be at least partially determined by the control signal of the auxiliary path, wherein the buffer is configured in particular as a folded cascode amplifier. A folded cascode amplifier is, in particular, a special type of operational amplifier that comprises multiple transistors and is configured to amplify an input signal. The amplifier preferably uses a cascode circuit, in which two transistors are connected in series in order to achieve higher gain. The folded cascode amplifier uses in particular an additional circuit in order to achieve higher gain and improved performance. Control via the auxiliary path can make the precise adjustment of the gain possible, by which a better signal-to-noise ratio can be achieved.

Advantageously, within the framework of the present invention, it can be provided that the electronic amplifier minimizes an error between the input signal of the buffer and an input signal of the electronic amplifier by means of the control signal, in particular regulating it to or toward 0. The electronic amplifier can measure a difference between the input signal at the buffer and its own input and generate a control current that compensates for this error. As a result, a more stable output signal is obtained and the precision and stability of the buffer are improved.

Furthermore, according to an example embodiment of the present invention, it is advantageous if the offset changes in the auxiliary path are minimized, in particular suppressed, in such a way that an input of the auxiliary path is modulated by controlling the arrangement of the chopper switches. This allows the accuracy of the control signal to be increased and thus the effectiveness of RTN suppression to be improved.

Furthermore, within the scope of the present invention, it is possible that the auxiliary path comprises at least two capacitors in order to reduce noise in the auxiliary path by means of the at least two capacitors, wherein preferably an offset of the auxiliary path is triangulated within the framework of the modulation using the at least two capacitors. The fact that the offset is triangulated within the framework of modulation means, in particular, that an offset (e.g., a deviation or error signal) is identified during the modulation process and corrected by measurements or calculations. The term “triangulate” specifically indicates that the exact value of this offset is determined by a plurality of measurements or samples of the signal. Subsequently, this offset can be compensated for in order to ensure more precise modulation and to minimize distortion or errors in the output signal.

A further advantage within the scope of the present invention can be achieved if the electronic circuit is provided for controlling a capacitive sensor, in particular as a reference for a sigma-delta analog-to-digital converter. Capacitive sensors measure, in particular, changes in capacitance between two electrodes, which are influenced by the proximity of an object or the change in a material. Examples of capacitive sensors that can be controlled by the electronic circuit according to the present invention are capacitive proximity sensors, capacitive displacement or distance sensors, capacitive pressure sensors or capacitive position sensors. These capacitive sensors can be used in technical systems such as user devices or vehicles. A sigma-delta analog-to-digital converter (sigma-delta ADC) is, in particular, a special type of analog-to-digital converter that is based on an oversampling and noise-shaping principle, in order to achieve very high accuracy in the digitization of analog signals.

The present invention also relates to a method for suppressing offset changes in a buffer. According to an example embodiment of the present invention, the method comprises:
providing an electronic circuit according to the present invention,
generating the control signal on the basis of the input signal by the electronic amplifier, wherein the control signal represents an error between the input signal of the buffer and an input signal of the electronic amplifier, wherein the generated control signal is fed to the buffer in order to suppress the offset changes.

The method according to the present invention thus delivers the same advantages as have been described in detail with reference to the electronic circuit according to the present invention. As a result, the electronic amplifier can react directly to deviations between the input signal of the buffer and its own input signal. This enables active error correction and thus efficient suppression of noise and offset changes in the buffer. Due to the method, the accuracy of the buffer can be improved.

Advantageously, according to an example embodiment of the present invention, the method can also comprise:
modulating the input of the auxiliary path by controlling the arrangement of chopper switches, in particular on the basis of a specified clock signal, wherein an offset of the auxiliary path is triangulated using the at least two capacitors.

In addition, it can be provided within the scope of the present invention that the method further comprises:
controlling and/or operating a capacitive sensor, in particular as a reference for a sigma-delta analog-to-digital converter, using the electronic circuit according to the present invention.

The present invention can also relate to a computer program, in particular a computer program product, comprising commands which, when the computer program is executed by a computer, cause the computer to carry out the method according to the present invention. The computer program according to the present invention thus delivers the same advantages as have been described in detail with reference to a method according to the present invention.

The present invention can also relate to a device for processing data that is configured to carry out the method according to the present invention. For example, a computer which executes the computer program according to the present invention can be provided as the device. The computer can have at least one processor for executing the computer program. A non-volatile data memory can also be provided, in which the computer program is stored and from which the computer program can be read by the processor for execution.

The present invention can also relate to a computer-readable storage medium which comprises the computer program according to the present invention and/or commands which, when executed by a computer, cause the computer to carry out the method according to the present invention. The storage medium is formed, for example, as a data memory such as a hard drive and/or a non-volatile memory and/or a memory card. The storage medium can be integrated into the computer, for example.

Furthermore, the method according to the present invention can also be designed as a computer-implemented method. Alternatively or additionally, at least one of the disclosed method steps can be computer-implemented and/or performed automatically.

Further advantages, features, and details of the present invention can be found in the following description, in which exemplary embodiments of the present invention are described in detail with reference to the figures. The features mentioned herein can be essential to the present invention in each case, either individually or in any combination.

### BRIEF DESCRIPTION OF THE DRAWINGS

FIG. 1 is a schematic visualization of a method, a capacitive sensor, and a sigma-delta analog-to-digital converter according to exemplary embodiments of the present invention.

FIG. 2 is a schematic representation of an electronic circuit according to exemplary embodiments of the present invention.

FIG. 3 is a schematic representation of a buffer according to exemplary embodiments of the present invention.

FIG. 4 is a schematic representation of an electronic circuit according to exemplary embodiments of the present invention.

FIG. 5 is a schematic representation of a triangulation according to exemplary embodiments of the present invention.

### DETAILED DESCRIPTION OF EXAMPLE EMBODIMENTS

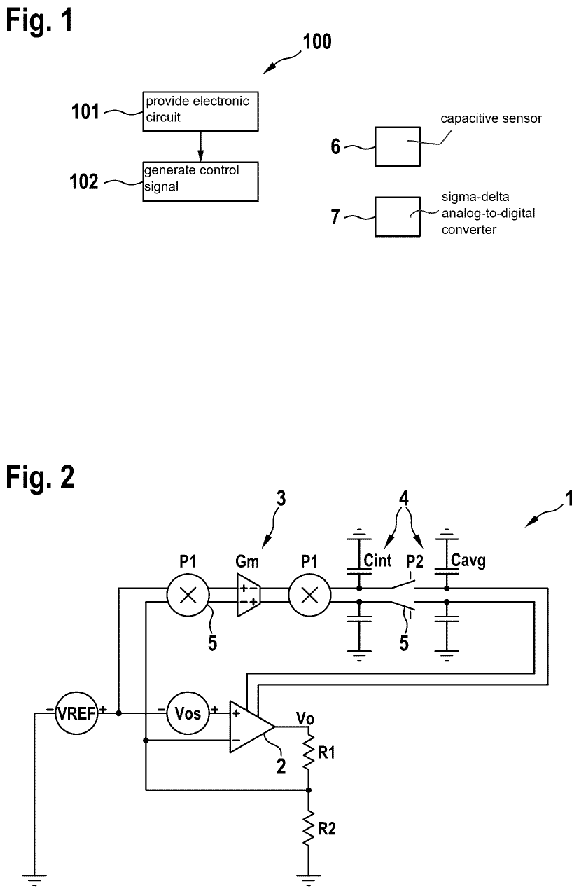

In FIG. 1, a method 100, a capacitive sensor 6 and a sigma-delta analog-to-digital converter 7 are schematically shown according to exemplary embodiments of the present invention.

FIG. 1 shows, in particular, an exemplary embodiment of a method 100 for suppressing offset changes in a buffer 2. In a first step 101, an electronic circuit 1 is provided according to exemplary embodiments of the present invention. In a third step 102, the control signal is generated on the basis of the input signal by the electronic amplifier 3, wherein the control signal represents an error between the input signal of the buffer 2 and an input signal of the electronic amplifier 3, wherein the generated control signal is fed to the buffer 2 in order to suppress the offset changes.

Within the scope of the present invention, a novel way is shown in particular to suppress random telegraph noise (RTN) or offsets in a reference buffer 2.

The electronic circuit 1 according to the present invention comprises in particular the following components: a buffer 2, an electronic amplifier 3, in particular a transconductance amplifier 3 (Gₘ), capacitors 4 (Cᵢₙₜ, C_{avg}) and chopper switches 5 (P1, P2), as shown in FIG. 2.

The buffer 2 preferably operates like a conventional control amplifier, so that the input signal V_{REF} appears at the output amplified by a factor of 1+R1/R2. Any offset Vₒₛ of the amplifier likewise appears at the output of the buffer 2, in particular in amplified form.

In parallel with the output, preferably an electronic amplifier in the form of a transconductance amplifier 3 (Gₘ) is arranged. This measures in particular the input signal V_{REF} and, for example, injects an additional control signal into a second stage of the amplifier A, which regulates to 0 an error between the two input signals V₁ and V₂ of the transconductance amplifier 3 (Gₘ) and of the main amplifier, i.e., the buffer 2. What is decisive here, in particular, is that an offset of the transconductance amplifier 3 (Gₘ) is entirely free of offset at the input of the auxiliary path thanks to the chopper circuit 5 and current integration. Furthermore, due to a filtering, the noise contribution of the auxiliary path can be significantly reduced.

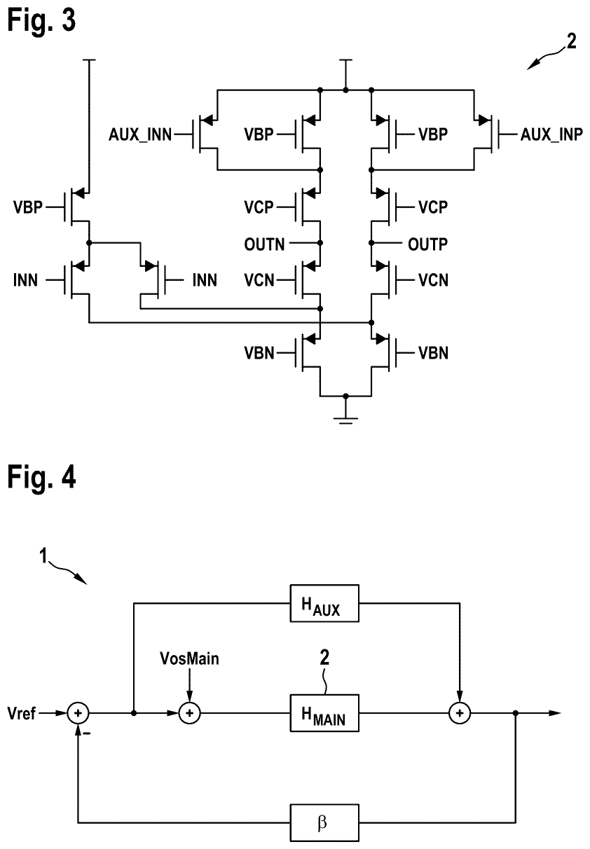

The main amplifier, or buffer 2, can be configured, e.g., as shown in FIG. 3, i.e., in particular as a “folded cascode” amplifier, in which an output PMOS current source is partially determined by the control signal of the auxiliary path (AUX_INN and AUX_INP). Thus, the output signal in the buffer 2 should be considered in particular as a superposition of both paths.

For the main path, the gain in this case is approximately, for example:

$${A}_{DCMain} = \frac{{V}_{o}}{{V}_{in}} = ℊ {m}_{main} * {R}_{0}$$

Starting from the input of the transconductance amplifier 3 (Gₘ) to the output AUX IN, the auxiliary path has, in particular, a discrete-time transfer function of the following form:

$${H}_{Aux} = {z}^{- 1} \cdot \frac{ℊ {m}_{aux} \cdot {T}_{INT}}{{C}_{AVG} + {C}_{INT}} * \frac{1}{1 - {z}^{- 1}}$$

The transconductance amplifier 3 (Gₘ) is thus in particular an integrating amplifier, by which infinite gain can occur at f=0, i.e., at direct current (DC).

$${H}_{Aux , DC} = ∞$$

Therefore, in particular, an overall transfer function of the auxiliary path arises as follows:

$${H}_{DCAux} = \frac{{V}_{o}}{{V}_{in , AUX}} = ℊ {m}_{current} * {R}_{Oaux} * {H}_{AUX}$$

This results in, in particular, an overall gain of:

$${A}_{DCMain , Full} = \frac{{V}_{o}}{{V}_{in}} = ℊ {m}_{main} * {R}_{0} + ℊ {m}_{current} * {R}_{Oaux} * {H}_{AUX}$$

Thus, the DC gain is significantly increased, since an additive term is added to the ordinary first portion of the gain, which is similar to the main path at gm_{current}*R₀ₐᵤₓ, but, by Hₐᵤₓ, is massively increased, in particular at low frequencies (theoretically infinite). However, the increased gain is primarily just a byproduct. The main task is preferably the suppression of offsets and RTN phenomena. This is now achieved for the main path. If an offset exists in the buffer 2, it is suppressed, in particular, by the auxiliary path.

This is shown in FIG. 4. Thus, VosMain, i.e., the noise or offset of the main path, can be suppressed to zero at frequency 0 by H_{Aux}, i.e., the discrete-time transfer function of the auxiliary path.

$${V}_{o} / {V}_{osMain} = \frac{{H}_{MAIN}}{1 + β \cdot ( {H}_{AUX} + {H}_{MAIN} )}$$

$${lim}_{{H}_{AUX} \to ∞} \frac{{H}_{MAIN}}{1 + β \cdot ( {H}_{AUX} + {H}_{MAIN} )} = 0$$

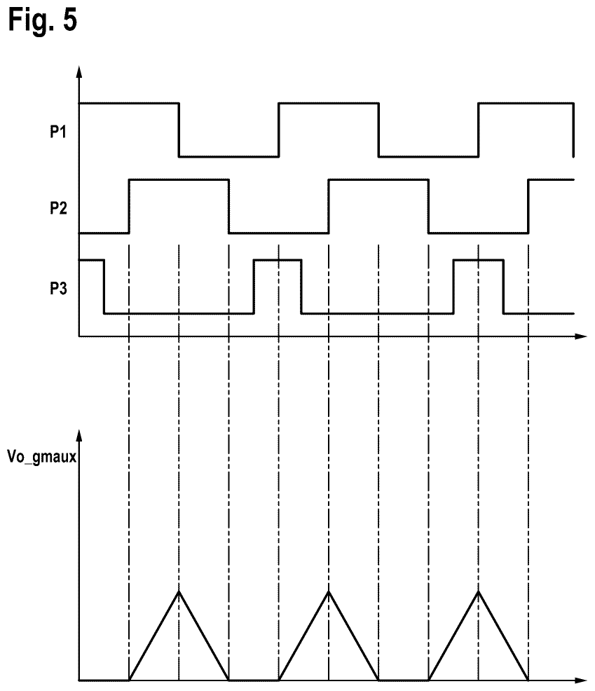

Finally, it is particularly necessary to clarify how an offset of the auxiliary path can be appropriately suppressed, since this would appear directly at the output without further measures. This can be achieved by triangulating the offset of the auxiliary path, i.e., the offset of the auxiliary path is preferably “averaged out” directly on the capacitor Cᵢₙₜ by means of a clocking scheme. This is shown graphically in FIG. 5.

In phase P1 & P2, i.e., when both chopper switches P1 and P2 are closed, the offset is in particular integrated positively, whereas in phase (not-P1) & P2, i.e., when only switch P2 is closed, this same offset is integrated negatively. Thus, at the end of each cycle, the following applies in particular:

$${V}_{AUXOFFSETOUT} = {V}_{osaux} + {Gm}_{aux} * \frac{T}{2} + ( - {V}_{osaux} ) * {Gm}_{aux} * \frac{T}{2} = 0$$

If Vₒₛₐᵤₓ is static during the measurement, the mean value is in particular 0, and the stated problem (offset+RTN) can thus be solved. Furthermore, the auxiliary path, due to its time integration, can in particular perform effective filtering of the noise of the transconductance amplifier 3 (Gₘ) on the capacitor 4 Cᵢₙₜ (to approximately half the operating frequency). Thus, broadband noise can be suppressed, which results in an excellent noise characteristic for the auxiliary path.

Advantages of the present invention include, in particular, the following: externally, it results in a chopper-ripple-free suppression of RIN and offset. Furthermore, minimal power consumption can be achieved in the auxiliary path by using an embedded noise filtering function. In addition, the DC gain can be increased massively, by which the main amplifier, or buffer 2, can be designed in a simple manner. Thus, the output of the buffer 2 does not necessarily have to provide any gain. This could allow for a simpler implementation of the buffer 2.

The present invention can be used, for example, in sensor interfaces of a technical system, according to exemplary embodiments.

The above description of the embodiments describes the present invention exclusively in the context of examples. Of course, individual features of the embodiments, provided they make technical sense, can be freely combined with one another without departing from the scope of the present invention.

1-11. (canceled)

12. An electronic circuit for suppressing offset changes in a buffer for providing an electrical output signal, the electronic circuit comprising:
the buffer, which is configured to provide the electrical output signal based on an input signal at an input of the electronic circuit, wherein the buffer is arranged in a main path of the electronic circuit;
an auxiliary path that is arranged parallel to the main path and includes at least the following elements:
an electronic amplifier, which is connected to the input to generate a control signal for the buffer based on the input signal, and
an arrangement of chopper switches configured to suppress offset changes in the auxiliary path by the arrangement of the chopper switches.

13. The electronic circuit according to claim 12, wherein the electronic amplifier is an integrating amplifier.

14. The electronic circuit according to claim 12, wherein the electrical output signal of the buffer is at least partially determined by the control signal of the auxiliary path, wherein the buffer is configured as a folded cascode amplifier.

15. The electronic circuit according to claim 12, wherein the electronic amplifier minimizes an error between the input signal of the buffer and an input signal of the electronic amplifier using the control signal, regulating it to or toward 0.

16. The electronic circuit according to 12, wherein the offset changes in the auxiliary path are suppressed in such a way that an input of the auxiliary path is modulated by controlling the arrangement of the chopper switches.

17. The electronic circuit according to claim 16, wherein the auxiliary path includes at least two capacitors to reduce noise in the auxiliary path using the at least two capacitors, wherein an offset of the auxiliary path is triangulated within a framework of the modulation using the at least two capacitors.

18. The electronic circuit according to claim 12, wherein the electronic circuit is provided for controlling a capacitive sensor as a reference for a sigma-delta analog-to-digital converter.

19. The electronic circuit according to claim 18, wherein the buffer is configured as a reference buffer in order to convert the input signal in the form of a high-impedance reference voltage into the output signal in a form of a low-impedance source voltage.

20. A method for suppressing offset changes in a buffer, comprising the following steps:
providing an electronic circuit for suppressing offset changes in a buffer for providing an electrical output signal, the electronic circuit including:
the buffer, which is configured to provide the electrical output signal based on an input signal at an input of the electronic circuit, wherein the buffer is arranged in a main path of the electronic circuit,
an auxiliary path that is arranged parallel to the main path and includes at least the following elements:
an electronic amplifier, which is connected to the input to generate a control signal for the buffer based on the input signal, and
an arrangement of chopper switches configured to suppress offset changes in the auxiliary path by the arrangement of the chopper switches;
generating the control signal based on the input signal by the electronic amplifier, wherein the control signal represents an error between the input signal of the buffer and an input signal of the electronic amplifier, wherein the generated control signal is fed to the buffer to suppress the offset changes.

21. The method according to claim 20, further comprising:
modulating the input of the auxiliary path by controlling the arrangement of chopper switches based on a specified clock signal, wherein an offset of the auxiliary path is triangulated using the at least two capacitors.

22. The method according to claim 20, further comprising:
controlling and/or operating a capacitive sensor as a reference for a sigma-delta analog-to-digital converter, using the electronic circuit.
